(19) United States
(12) Patent Application Publication
(10) Pub. No.: US 2024/0128982 A1
(43) Pub. Date: Apr. 18, 2024

(54) HARDWARE ACCELERATION OF DATA REDUCTION OPERATIONS

(71) Applicant: Intel Corporation, Santa Clara, CA (US)

(72) Inventors: Smita Kumar, Chandler, AZ (US); Patrick Fleming, Laois (IE)

(73) Assignee: Intel Corporation, Santa Clara, CA (US)

(21) Appl. No.: 18/397,651

(22) Filed: Dec. 27, 2023

(51) Int. Cl. H03M 7/30; H03M 7/32

(52) U.S. Cl. CPC H03M 7/3068; H03M 7/3048

(57) ABSTRACT

A hardware accelerator device is provided with circuitry to perform one or more reversible data transforms on data based on a request and compress the transformed data to generate compressed transformed data. The hardware accelerator device generates an output including the compressed transformed data and transform metadata indicating the set of reversible data transforms applied to the compressed transformed data.

### FIELD

The present disclosure relates in general to the field of distributed computing systems, and more specifically, to applying reversible data transforms using a hardware accelerator.

### BACKGROUND

A datacenter may include one or more platforms each comprising at least one processor and associated memory modules. Each platform of the datacenter may facilitate the performance of any suitable number of processes associated with various applications running on the platform. These processes may be performed by the processors and other associated logic of the platforms. Each platform may additionally include I/O controllers, such as network adapter devices, which may be used to send and receive data on a network for use by the various applications.

### BRIEF DESCRIPTION OF THE DRAWINGS

FIG. 1 illustrates a block diagram of components of a datacenter in accordance with certain embodiments.

FIG. 2 is a simplified block diagram of an example platform including a hardware accelerator.

FIG. 3 is a simplified block diagram illustrating an example logical stack for a hardware accelerator used by one or more applications in an example computing platform.

FIG. 4 is a simplified block diagram illustrating an example data transform and compression process.

FIG. 5 is a simplified block diagram illustrating an example linked list of data transforms to be included in a data reduction request.

FIG. 6 is a simplified block diagram illustrating example inputs of an example hardware accelerator.

FIG. 7 is a simplified block diagram illustrating an example decompression operation.

FIG. 8 is a simplified block diagram illustrating the example application of a sequence of data transforms and corresponding reverse data transforms.

FIG. 9 is a simplified block diagram illustrating an example data transform and corresponding reverse data transform.

FIG. 10 is a flow diagram illustrating example techniques for performing data reduction using a hardware accelerator and performing a corresponding data restoration.

FIG. 11 illustrates a block diagram of an example processor device in accordance with certain embodiments.

Like reference numbers and designations in the various drawings indicate like elements.

### DETAILED DESCRIPTION

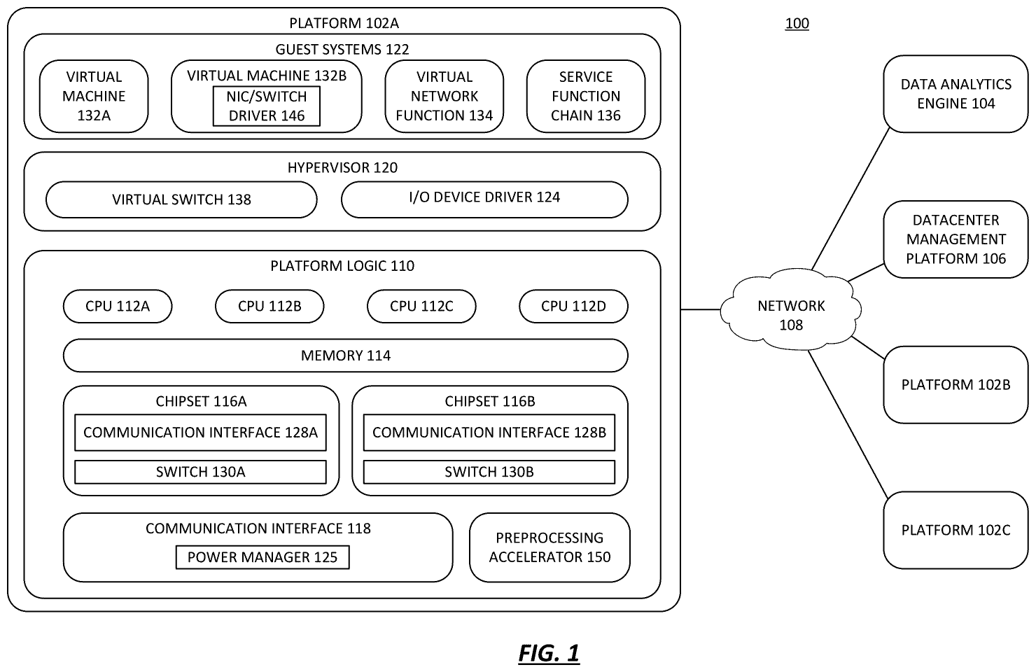

FIG. 1 illustrates a block diagram of components of a datacenter 100 in accordance with certain embodiments. In the embodiment depicted, datacenter 100 includes a plurality of platforms 102, data analytics engine 104, and datacenter management platform 106 coupled together through network 108. A platform 102 may include platform logic 110 with one or more central processing units (CPUs) 112, memories 114 (which may include any number of different modules), chipsets 116, communication interfaces 118, and any other suitable hardware and/or software to execute a hypervisor 120 or other operating system capable of executing processes associated with applications running on platform 102. In some embodiments, a platform 102 may function as a host platform for one or more guest systems 122 that invoke these applications. The platform may be logically or physically subdivided into clusters and these clusters may be enhanced through specialized networking accelerators and the use of Compute Express Link (CXL) memory semantics to make such cluster more efficient, among other example enhancements.

Each platform 102 may include platform logic 110. Platform logic 110 comprises, among other logic enabling the functionality of platform 102, one or more CPUs 112, memory 114, one or more chipsets 116, and communication interface 118. Although three platforms are illustrated, datacenter 100 may include any suitable number of platforms. In various embodiments, a platform 102 may reside on a circuit board that is installed in a chassis, rack, compossible servers, disaggregated servers, or other suitable structures that comprises multiple platforms coupled together through network 108 (which may comprise, e.g., a rack or backplane switch). In still other examples, the platform or portions of the platform (including a preprocessing hardware accelerator (e.g., 150) may be integrated within other computing systems and form factors, including personal computers, set top boxes, gaming system, smart appliances, IoT systems, smart phones, vehicle onboard systems, among other examples.

CPUs 112 may each comprise any suitable number of processor cores. The cores may be coupled to each other, to memory 114, to at least one chipset 116, and/or to communication interface 118, through one or more controllers residing on CPU 112 and/or chipset 116. In particular embodiments, a CPU 112 is embodied within a socket that is permanently or removably coupled to platform 102. Although four CPUs are shown, a platform 102 may include any suitable number of CPUs. In some implementations, application to be executed using the CPU (or other processors) may include physical layer management applications, which may enable customized software-based configuration of the physical layer of one or more interconnect used to couple the CPU (or related processor devices) to one or more other devices in a data center system.

Memory 114 may comprise any form of volatile or non-volatile memory including, without limitation, magnetic media (e.g., one or more tape drives), optical media, random access memory (RAM), read-only memory (ROM), flash memory, removable media, or any other suitable local or remote memory component or components. Memory 114 may be used for short, medium, and/or long-term storage by platform 102. Memory 114 may store any suitable data or information utilized by platform logic 110, including software embedded in a computer readable medium, and/or encoded logic incorporated in hardware or otherwise stored (e.g., firmware). Memory 114 may store data that is used by cores of CPUs 112. In some embodiments, memory 114 may also comprise storage for instructions that may be executed by the cores of CPUs 112 or other processing elements (e.g., logic resident on chipsets 116) to provide functionality associated with components of platform logic 110. Additionally or alternatively, chipsets 116 may each comprise memory that may have any of the characteristic s described herein with respect to memory 114. Memory 114 may also store the results and/or intermediate results of the various calculations and determinations performed by CPUs 112 or processing elements on chipsets 116. In various embodiments, memory 114 may comprise one or more modules of system memory coupled to the CPUs through memory controllers (which may be external to or integrated with CPUs 112). In various embodiments, one or more particular modules of memory 114 may be dedicated to a particular CPU 112 or other processing device or may be shared across multiple CPUs 112 or other processing devices.

A platform 102 may also include one or more chipsets 116 comprising any suitable logic to support the operation of the CPUs 112. In various embodiments, chipset 116 may reside on the same package as a CPU 112 or on one or more different packages. Each chipset may support any suitable number of CPUs 112. A chipset 116 may also include one or more controllers to couple other components of platform logic 110 (e.g., communication interface 118 or memory 114) to one or more CPUs. Additionally or alternatively, the CPUs 112 may include integrated controllers. For example, communication interface 118 could be coupled directly to CPUs 112 via integrated I/O controllers resident on each CPU.

Chipsets 116 may each include one or more communication interfaces 128. Communication interface 128 may be used for the communication of signaling and/or data between chipset 116 and one or more I/O devices, one or more networks 108, and/or one or more devices coupled to network 108 (e.g., datacenter management platform 106 or data analytics engine 104). For example, communication interface 128 may be used to send and receive network traffic such as data packets. In a particular embodiment, communication interface 128 may be implemented through one or more I/O controllers, such as one or more physical network interface controllers (NICs), also known as network interface cards or network adapters. An I/O controller may include electronic circuitry to communicate using any suitable physical layer and data link layer standard such as Ethernet (e.g., as defined by an IEEE 802.3 standard), Fibre Channel, InfiniB and, Wi-Fi, or other suitable standard. An I/O controller may include one or more physical ports that may couple to a cable (e.g., an Ethernet cable). An I/O controller may enable communication between any suitable element of chipset 116 (e.g., switch 130) and another device coupled to network 108. In some embodiments, network 108 may comprise a switch with bridging and/or routing functions that is external to the platform 102 and operable to couple various I/O controllers (e.g., NICs) distributed throughout the datacenter 100 (e.g., on different platforms) to each other. In various embodiments an I/O controller may be integrated with the chipset (i.e., may be on the same integrated circuit or circuit board as the rest of the chipset logic) or may be on a different integrated circuit or circuit board that is electromechanically coupled to the chipset. In some embodiments, communication interface 128 may also allow I/O devices integrated with or external to the platform (e.g., disk drives, other NICs, etc.) to communicate with the CPU cores.

Switch 130 may couple to various ports (e.g., provided by NICs) of communication interface 128 and may switch data between these ports and various components of chipset 116 according to one or more link or interconnect protocols, such as Peripheral Component Interconnect Express (PCIe), Compute Express Link (CXL), HyperTransport, GenZ, OpenCAPI, and others, which may each alternatively or collectively apply the general principles and/or specific features discussed herein. Switch 130 may be a physical or virtual (i.e., software) switch.

Platform logic 110 may include an additional communication interface 118. Similar to communication interface 128, communication interface 118 may be used for the communication of signaling and/or data between platform logic 110 and one or more networks 108 and one or more devices coupled to the network 108. For example, communication interface 118 may be used to send and receive network traffic such as data packets. In a particular embodiment, communication interface 118 comprises one or more physical I/O controllers (e.g., NICs). These NICs may enable communication between any suitable element of platform logic 110 (e.g., CPUs 112) and another device coupled to network 108 (e.g., elements of other platforms or remote nodes coupled to network 108 through one or more networks). In particular embodiments, communication interface 118 may allow devices external to the platform (e.g., disk drives, other NICs, etc.) to communicate with the CPU cores. In various embodiments, NICs of communication interface 118 may be coupled to the CPUs through I/O controllers (which may be external to or integrated with CPUs 112). Further, as discussed herein, I/O controllers may include a power manager 125 to implement power consumption management functionality at the I/O controller (e.g., by automatically implementing power savings at one or more interfaces of the communication interface 118 (e.g., a PCIe interface coupling a NIC to another element of the system), among other example features.

Platform logic 110 may receive and perform any suitable types of processing requests. A processing request may include any request to utilize one or more resources of platform logic 110, such as one or more cores or associated logic. For example, a processing request may comprise a processor core interrupt; a request to instantiate a software component, such as an I/O device driver 124 or virtual machine 132; a request to process a network packet received from a virtual machine 132 or device external to platform 102 (such as a network node coupled to network 108); a request to execute a workload (e.g., process or thread) associated with a virtual machine 132, application running on platform 102, hypervisor 120 or other operating system running on platform 102; or other suitable request.

In various embodiments, processing requests may be associated with guest systems 122. A guest system may comprise a single virtual machine (e.g., virtual machine 132a or 132b) or multiple virtual machines operating together (e.g., a virtual network function (VNF) 134 or a service function chain (SFC) 136). As depicted, various embodiments may include a variety of types of guest systems 122 present on the same platform 102.

A virtual machine 132 may emulate a computer system with its own dedicated hardware. A virtual machine 132 may run a guest operating system on top of the hypervisor 120. The components of platform logic 110 (e.g., CPUs 112, memory 114, chipset 116, and communication interface 118) may be virtualized such that it appears to the guest operating system that the virtual machine 132 has its own dedicated components.

A virtual machine 132 may include a virtualized NIC (vNIC), which is used by the virtual machine as its network interface. A vNIC may be assigned a media access control (MAC) address, thus allowing multiple virtual machines 132 to be individually addressable in a network.

In some embodiments, a virtual machine 132b may be paravirtualized. For example, the virtual machine 132b may include augmented drivers (e.g., drivers that provide higher performance or have higher bandwidth interfaces to underlying resources or capabilities provided by the hypervisor 120). For example, an augmented driver may have a faster interface to underlying virtual switch 138 for higher network performance as compared to default drivers.

VNF 134 may comprise a software implementation of a functional building block with defined interfaces and behavior that can be deployed in a virtualized infrastructure. In particular embodiments, a VNF 134 may include one or more virtual machines 132 that collectively provide specific functionalities (e.g., wide area network (WAN) optimization, virtual private network (VPN) termination, firewall operations, load-balancing operations, security functions, etc.). A VNF 134 running on platform logic 110 may provide the same functionality as traditional network components implemented through dedicated hardware. For example, a VNF 134 may include components to perform any suitable NFV workloads, such as virtualized Evolved Packet Core (vEPC) components, Mobility Management Entities, 3rd Generation Partnership Project (3GPP) control and data plane components, etc.

SFC 136 is a group of VNFs 134 organized as a chain to perform a series of operations, such as network packet processing operations. Service function chaining may provide the ability to define an ordered list of network services (e.g., firewalls, load balancers) that are stitched together in the network to create a service chain.

A hypervisor 120 (also known as a virtual machine monitor) may comprise logic to create and run guest systems 122. The hypervisor 120 may present guest operating systems run by virtual machines with a virtual operating platform (i.e., it appears to the virtual machines that they are running on separate physical nodes when they are actually consolidated onto a single hardware platform) and manage the execution of the guest operating systems by platform logic 110. Services of hypervisor 120 may be provided by virtualizing in software or through hardware assisted resources that require minimal software intervention, or both. Multiple instances of a variety of guest operating systems may be managed by the hypervisor 120. Each platform 102 may have a separate instantiation of a hypervisor 120.

Hypervisor 120 may be a native or bare-metal hypervisor that runs directly on platform logic 110 to control the platform logic and manage the guest operating systems. Alternatively, hypervisor 120 may be a hosted hypervisor that runs on a host operating system and abstracts the guest operating systems from the host operating system. Various embodiments may include one or more non-virtualized platforms 102, in which case any suitable characteristics or functions of hypervisor 120 described herein may apply to an operating system of the non-virtualized platform.

Hypervisor 120 may include a virtual switch 138 that may provide virtual switching and/or routing functions to virtual machines of guest systems 122. The virtual switch 138 may comprise a logical switching fabric that couples the vNICs of the virtual machines 132 to each other, thus creating a virtual network through which virtual machines may communicate with each other. Virtual switch 138 may also be coupled to one or more networks (e.g., network 108) via physical NICs of communication interface 118 so as to allow communication between virtual machines 132 and one or more network nodes external to platform 102 (e.g., a virtual machine running on a different platform 102 or a node that is coupled to platform 102 through the Internet or other network). Virtual switch 138 may comprise a software element that is executed using components of platform logic 110. In various embodiments, hypervisor 120 may be in communication with any suitable entity (e.g., a SDN controller) which may cause hypervisor 120 to reconfigure the parameters of virtual switch 138 in response to changing conditions in platform 102 (e.g., the addition or deletion of virtual machines 132 or identification of optimizations that may be made to enhance performance of the platform).

Hypervisor 120 may include any suitable number of I/O device drivers 124. I/O device driver 124 represents one or more software components that allow the hypervisor 120 to communicate with a physical I/O device. In various embodiments, the underlying physical I/O device may be coupled to any of CPUs 112 and may send data to CPUs 112 and receive data from CPUs 112. The underlying I/O device may utilize any suitable communication protocol, such as PCI, PCIe, Universal Serial Bus (USB), Serial Attached SCSI (SAS), Serial ATA (SATA), InfiniBand, Fibre Channel, an IEEE 802.3 protocol, an IEEE 802.11 protocol, or other current or future signaling protocol.

The underlying I/O device may include one or more ports operable to communicate with cores of the CPUs 112. In one example, the underlying I/O device is a physical NIC or physical switch. For example, in one embodiment, the underlying I/O device of I/O device driver 124 is a NIC of communication interface 118 having multiple ports (e.g., Ethernet ports).

In other embodiments, underlying I/O devices may include any suitable device capable of transferring data to and receiving data from CPUs 112, such as an audio/video (A/V) device controller (e.g., a graphics accelerator or audio controller); a data storage device controller, such as a flash memory device, magnetic storage disk, or optical storage disk controller; a wireless transceiver; a network processor; or a controller for another input device such as a monitor, printer, mouse, keyboard, or scanner; or other suitable device.

In various embodiments, when a processing request is received, the I/O device driver 124 or the underlying I/O device may send an interrupt (such as a message signaled interrupt) to any of the cores of the platform logic 110. For example, the I/O device driver 124 may send an interrupt to a core that is selected to perform an operation (e.g., on behalf of a virtual machine 132 or a process of an application). Before the interrupt is delivered to the core, incoming data (e.g., network packets) destined for the core might be cached at the underlying I/O device and/or an I/O block associated with the CPU 112 of the core. In some embodiments, the I/O device driver 124 may configure the underlying I/O device with instructions regarding where to send interrupts.

In some embodiments, as workloads are distributed among the cores, the hypervisor 120 may steer a greater number of workloads to the higher performing cores than the lower performing cores. In certain instances, cores that are exhibiting problems such as overheating or heavy loads may be given less tasks than other cores or avoided altogether (at least temporarily). Workloads associated with applications, services, containers, and/or virtual machines 132 can be balanced across cores using network load and traffic patterns rather than just CPU and memory utilization metrics.

The elements of platform logic 110 may be coupled together in any suitable manner. For example, a bus may couple any of the components together. A bus may include any known interconnect, such as a multi-drop bus, a mesh interconnect, a ring interconnect, a point-to-point interconnect, a serial interconnect, a parallel bus, a coherent (e.g., cache coherent) bus, a layered protocol architecture, a differential bus, or a Gunning transceiver logic (GTL) bus.

Elements of the data system 100 may be coupled together in any suitable manner such as through one or more networks 108. A network 108 may be any suitable network or combination of one or more networks operating using one or more suitable networking protocols. A network may represent a series of nodes, points, and interconnected communication paths for receiving and transmitting packets of information that propagate through a communication system. For example, a network may include one or more firewalls, routers, switches, security appliances, antivirus servers, or other useful network devices. A network offers communicative interfaces between sources and/or hosts, and may comprise any local area network (LAN), wireless local area network (WLAN), metropolitan area network (MAN), Intranet, Extranet, Internet, wide area network (WAN), virtual private network (VPN), cellular network, or any other appropriate architecture or system that facilitates communications in a network environment. A network can comprise any number of hardware or software elements coupled to (and in communication with) each other through a communications medium. In various embodiments, guest systems 122 may communicate with nodes that are external to the datacenter 100 through network 108.

In some implementations, the data system 100 may include one or more hardware accelerator devices (e.g., 150) to assist with tasks of the data system 100 and to “accelerate” certain common tasks of the system 100 so as to increase the overall efficiency of the system and applications executed on the system (e.g., from a latency, bandwidth, or power perspective). In one example, a preprocessing accelerator device 150 may be provided on the data system 100, with hardware-implemented logic to perform a set of functions or algorithms commonly used within the data system. As an example, the preprocessing accelerator 150 may include circuitry to perform compression/decompression, encryption/decryption, and other tasks, including applying data transforms, such as discussed further herein. The exponential growth of data- and compute-intensive workloads such as artificial intelligence (AI), analytics, high-performance storage, and cloud application services has placed increasing demands on a data system's CPU(s) and other hardware (e.g., memory, I/O, etc.). As an example, managing encrypted data resources has become common practice. Further, applications that involve compression and encryption of data in a single pass can significantly tie up processing resources and add data-flow bottlenecks, leading to increased latency. Indeed, even standard compression algorithms can consume significant CPU resources. To address these and other example issues, a preprocessing accelerator may be included (e.g., as a standalone accelerator device, built-in accelerator, or add-in card), through which certain computationally intensive operations (e.g., symmetric and asymmetric cryptography, data compression/decompression operations, data transforms, etc.) can be offloaded from the CPU, allowing computational resources to be reallocated to allow the CPU to perform other tasks more efficiently, potentially enhancing overall system performance, efficiency, and power across various use cases, among other example advantages.

Modern computing systems face increasing demands on their memory and communication bandwidth, as they are tasked with communicating, buffering, and processing increasing quantities of data of varying types. For instance, in Internet of Things (IoT)-type applications, time series data may be generated by various IoT sensors, event logs, web or mobile analytics, enterprise servers, and other sources and may be stored in specialized time-series databases that are tailored for such data. For instance, columnar databases hold strongly typed datasets such as INT, FLOAT, DATE, TIME, etc. In some implementations, the data in these databases is stored in a compressed format to manage data efficiently. Various compression algorithms may be used to perform such compressions, including LZ77 algorithms such as ZSTD, LZ4, Snappy, among other examples. When compression is performed by a CPU (e.g., in advance of the data being moved to memory or communicated over a bus or network interface), large amounts of data are typically transferred to/from the CPU cache, where the data resides while the compute intensive compression transforms are performed. The faster the computation, the lower the cache residency time and therefore improved utilization of cache. Accordingly, acceleration of compression algorithms in hardware greatly reduces the latency of the overall compression operation, thereby reducing CPU compute cycles and improving cache utilization, among other example benefits.

In addition to improving CPU and overall system performance, reversible transform operations may be integrated within a hardware accelerator device. With the constant need to reduce data footprint the integration of reversible transforms to make data more amenable to subsequent compression is a powerful approach to further reducing data footprint within a system, as well as providing further efficiencies. However, reversible data transforms are also compute-intensive and typically require that operation on an entire data set be completed before the “transformed” dataset can be compressed, thereby increasing overall latency as well as the utilization of cache and CPU cycles. In traditional systems, reversible data transforms are implemented in software and the results of the transforms are then passed to compression software or hardware. Some examples of reversible data transforms include Integer transforms (e.g., delta, double-delta transforms, Gorilla (XOR transform), bitshuffle, byteshuffle, T64 (e.g., removal of unused most significant bits, etc.), Floating Point transforms (e.g., Gorilla (XOR transform), etc.), Text transforms (e.g., Burrows-Wheeler transform, Move-to-front, etc.), among other examples. In an improved preprocessing accelerator, compute circuitry of the accelerator may implement a set of reversible transforms to enable the entire operation to be accelerated as a single pipelined operation. Such a solution offers data footprint optimizations without the associated increase in CPU cycle cost, compression latency, or cache utilization, among other example advantages.

Traditionally, the implementation of reversible transforms has been the domain of software, where software solutions are relied upon to implement various preprocessing tasks, including compression and decompression. To the extent that systems implement compression/decompression in concert with a reversible transform, such solutions have been implemented as two independent functions. Accordingly, traditional solutions suffer from the drawback of increased memory bandwidth, higher latency, higher CPU cycle cost and reduced cache utilization in order to realize gains in compression ratio. Some solutions may utilize software to perform a data transform and pass the transformed data to a hardware based compression engine. Similarly, the reverse transform can be applied by software after decompression by a hardware or software-based decompression engine. However, a drawback of this approach is, again, higher latency, more CPU cycles, and additional I/O operations to/from cache, among other example issues.

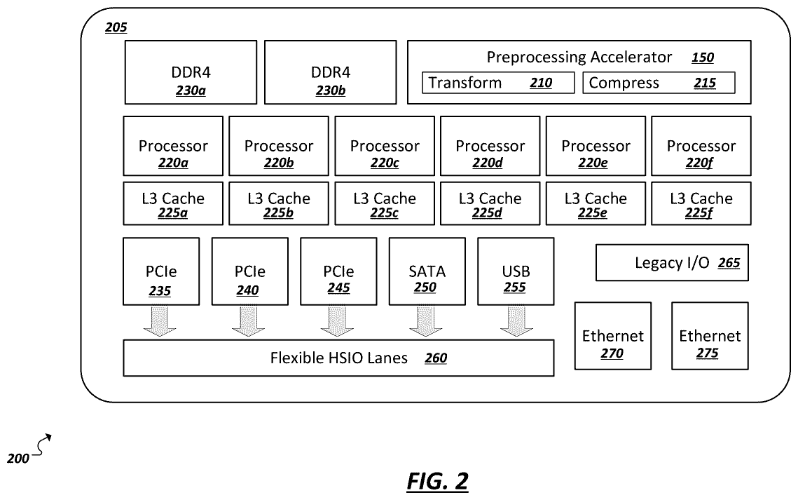

In an improved data processing system, a hardware accelerator may be provided with inbuilt support for both reversible data transform operations and compression operations. The data transform functionality of the accelerator may integrate corresponding preprocessing codes within a compression pipeline to enable lower latency, better cache utilization, and lower memory bandwidth consumption, among other example benefits. Turning to FIG. 2, a simplified block diagram 200 is shown of an example processing device 205, such as implemented in a system on chip (SoC), processor device, motherboard, or another computing platform. In this example, an improved preprocessing hardware accelerator 150 may be provided. The preprocessing hardware accelerator 150 may include circuitry (e.g., 210) to implement a set of data transforms and a corresponding set of reverse data transforms, as well as circuitry (e.g., 215) to perform compression and decompression of data according to one or multiple lossless compression algorithms. The hardware accelerator 150 may also provide other functionality, which may be utilized to pre-process (or post-process) data for the system, such as cryptographic operations and other examples. The hardware accelerator 150 allows for these operations to be offloaded from the general purpose processing cores (e.g., CPUs), which may otherwise be call upon to perform such operations (e.g., through the execution of corresponding software or firmware code). In this example, the data processing system 205 may include one more processor devices 220a-f with corresponding cache blocks 225a-f (e.g., level 3 (L3) cache). System memory 230a-b (e.g., implemented using DDR4 memory blocks) may be provided and further used by the processors 225a-f and hardware accelerator 150, among other elements of the data processing system. In some implementations, source and destination buffers may be implemented in cache 225a-f or system memory 230a-b. I/O circuitry may be provided to couple components to the memory 203a-b. Additional I/O circuitry (e.g., 235, 240, 245, 250, 255, 265, 270, 275) may be provided to allow the data processing system 205 to interface and communicate with external devices, for instance, over flexible high speed I/O (HSIO) lanes 260.

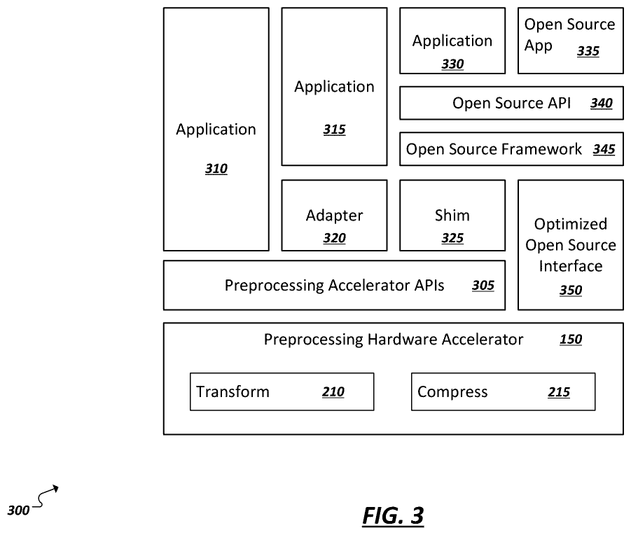

Turning to the simplified block diagram 300 in FIG. 3, a representation of a logic stack for implementing applications (e.g., 310, 315, 330, 335), which may leverage the functionality of preprocessing hardware accelerator 150. In some implementations, one or more application programming interfaces (APIs) may be provided to allow applications to request the hardware accelerator to perform, using the hardware circuitry of the hardware accelerator 150, one or a series of reversible data transforms and/or a lossless compression algorithm (e.g., immediately following the data transforms). Some applications (e.g., 310) may directly access the accelerator API 305, while other applications (e.g., 315, 330, 335, etc.) may utilize adapters (e.g., 320), shims (e.g., 325), open source APIs and adapters (e.g., 340, 345, 350), among other example features and implementations.

In one example implementation, The accelerator API 305 may define a compression API call to allow transform and compression operations of the hardware accelerator 150 to be requested. In one example, the compression API call specifies the number of transforms (e.g., 0-15) and the order/granularity in which they are to be applied. The hardware accelerator may read, in a request made through the compression API call, transform metadata and the source data to be transformed and compressed (e.g., from DRAM, cache, or a peer device) into the accelerator 150. The hardware accelerator 150 circuitry parses the transform metadata to determine the transforms that are to be applied, and then applies the specified transform(s) in the order indicated in the request by the application (e.g., as programmed by an end user) and then compresses the transformed data with compression circuitry (e.g., a LZ77 compressor) of the hardware accelerator 150. In some implementations, the hardware accelerator 150 may support multiple compression algorithms and requests provided through the compression API call may also specify which of the supported compression algorithms is to be implemented. The resulting transformed/compressed data and the associated (unchanged) transform metadata may then be written to memory (e.g., DRAM), a peer device, a database, or another destination.

In the case of decompression/reverse transforms, a decompression API may be provided in the hardware accelerator API 305. In one example, the decompression API specifies the set of (reverse) data transforms (e.g., 0-15) and the order/granularity in which they are to be applied. The decompression circuitry of the hardware accelerator 150 may read the transform metadata provided in a decompression request made through the decompression API and the associated the source data to be decompressed (e.g., from DRAM or a peer device) into the hardware accelerator 150. The hardware accelerator 150 may parse the transform metadata to determine the (reverse) transforms that are to be applied after decompression to restore the compressed-transformed data to its original state. Corresponding hardware circuitry of the hardware accelerator 150 is then selected to first appropriately decompress the data and then reverse the transforms to restore the original data, before writing the decompressed data to a destination (e.g., DRAM, a peer device, etc.).

An improved preprocessing hardware accelerator (e.g., 150) may be implemented to perform a combined data reduction operation of one or more reversible data transforms followed by a lossless compression in a single offload operation. Similarly, the preprocessing hardware accelerator (e.g., 150) may perform a combined data recovery operation involving a corresponding decompression and corresponding reverse data transforms in a single offload operation. Accordingly, the use of such a hardware accelerator allows valuable CPU cycles to be saved and reduces read-write cycles to memory (e.g., traditional software-based transforms and compression involve at least a two-pass process), while also improving cache utilization. In some cases, the preprocessing hardware accelerator may also include circuitry to complete a verification function to verify that decompressed data matches the original data and a compress and verify function may also be performed in the single offload, among other example features.

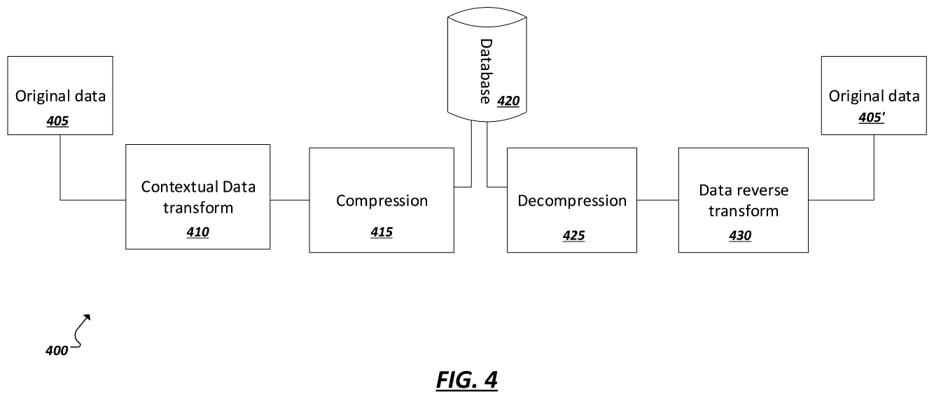

Turning to FIG. 4, a simplified block diagram 400 is shown illustrating the generalized flow of a combined data reduction operation and combined data recovery operation using an improved preprocessing hardware accelerator. Original data 405 is accessed (e.g., from a source buffer) by the hardware accelerator and one or more contextual, reversible data transforms 410 are applied to the data 405 (e.g., when requested through the hardware accelerator API). Once the data transform(s) are applied to the data 405, the transformed data may be provided as an input to the compression hardware circuitry of the hardware accelerator to compress the transformed data. The resulting compressed data may be more compact given the applied data transforms than if the data were compressed using the compression circuitry alone. The compressed data may be written to a destination (e.g., database 420 or another internal or external device). The compressed data may be accessed by the same or a different system possessing an instance of the hardware accelerator to determine (e.g., from metadata attached or otherwise associated with the compressed data) the data transforms (if any) that were applied and may decompress (at 425) the data before applying any reverse data transforms 430 based on the metadata, to restore the data to the original data 405′. In some implementations, to manage the physical footprint of the hardware accelerator, limited quantities of data may be provided to the hardware accelerator at a time. This may allow for hardware accelerator designs to support multiple data transforms, with the circuitry implementing each respective data transform occupying comparatively little area overhead, given that only relatively small sections of data (e.g., less than 4 GB) are operated upon at a time. For instance, the granularity of data operated upon in a transform or reverse-transform may be smaller than the granularity of data operated upon in a compression or decompression (e.g., with a maximum compression request length of 4 GB), among other example features and considerations.

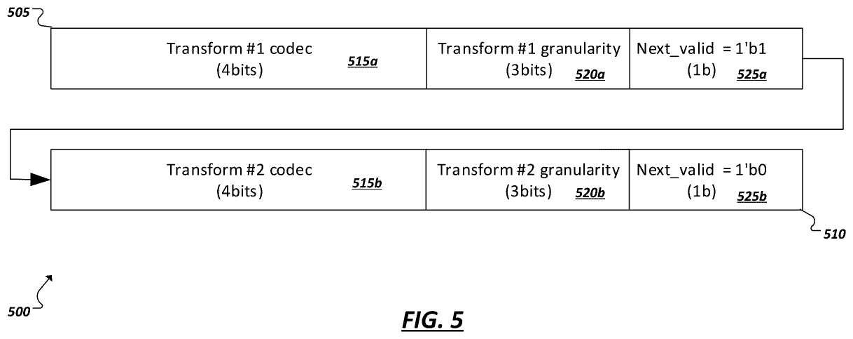

In one example implementation, the list of transforms to be applied in a combined data reduction operation to be performed by a preprocessing hardware accelerator, may be provided through a linked list at the API level. For instance, the link list may identify the specific transforms to be applied (from among the transforms supported by the hardware accelerator) together with the order in which the set of transforms is to be applied within the linked list. For instance, FIG. 5 is a block diagram 500 illustrating a representation of at least a portion of an example implementation of a link list to be included in a compression request submitted through a call to the API of the hardware accelerator. In this example, each entry (e.g., 505, 510) in the linked list submitted through the API call may include a first field (e.g., 515a-b) to name the selected transform (e.g., by a transform identifier), with a second field (e.g., 520a-b) indicating the granularity of the transform (e.g., 8b granularity, 16b granularity, 32 bit granularity, etc.), and the third field (e.g., 525a-b) serving as a next valid field to point to the next entry (e.g., 510) in the linked list. If the next valid field of a given entry (e.g., 510) is a null value (or other value to indicate that no other entries are in the list), this indicates that the corresponding transform (e.g., as indicated in 515b) is the final transform to be performed on the data included in the API call. In some cases, no transforms may be requested with a given compression API call. In one example implementation, if no transforms are requested to be performed with the compression, a NULL pointer may be passed in the API call.

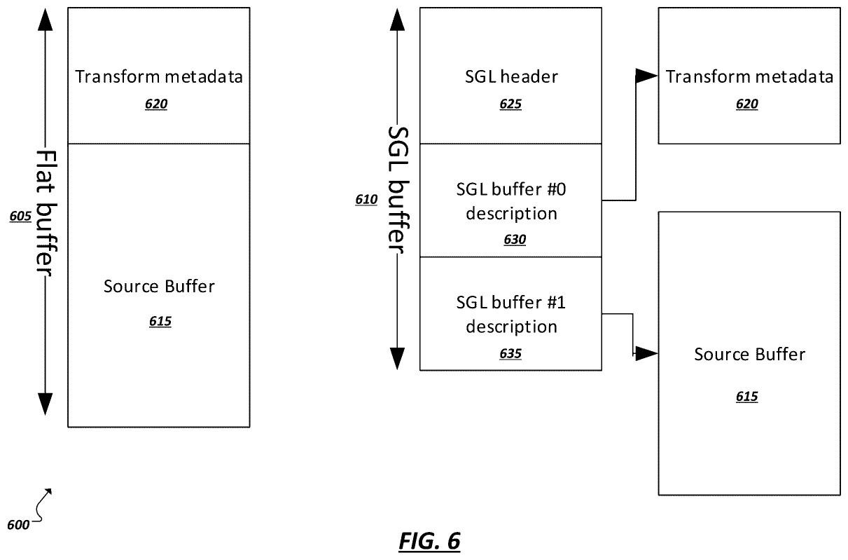

In some implementations, a driver associated with the preprocessing hardware accelerator may receive the data and linked link and convert the linked list into a transform metadata structure to be appended to or otherwise associated with the data to be compressed. In one example, the length of the generated transform metadata may be based on the number of transforms enumerated in the link list. FIG. 6 is a block diagram 600 representing examples of source buffers (e.g., 605, 610) accessible by the preprocessing hardware accelerator to obtain the data to be transformed (e.g., 615) with the corresponding transform metadata (e.g., 620) (e.g., as generated from a linked list (or other transform request data) included in a compression API call). The preprocessing hardware accelerator may include logic (e.g., implemented in hardware circuitry or firmware) to parse the transform metadata to identify whether there are data transforms to apply, which transforms are requested, and what order the transforms should be applied to the data 615 in the request. In one example, the determined transforms may be indicated in a firmware descriptor interface of the hardware accelerator. In some implementations, the source data 615 and transform metadata may be held in a non-contiguous form, such as using a scatter gather list (SGL) buffer or other structure, among other examples. For instance, an SGL buffer 610 may be used, including an SGL header 625 and pointers (e.g., 630, 635) to respective memory locations holding the source data 615 and the associated transform metadata 620.

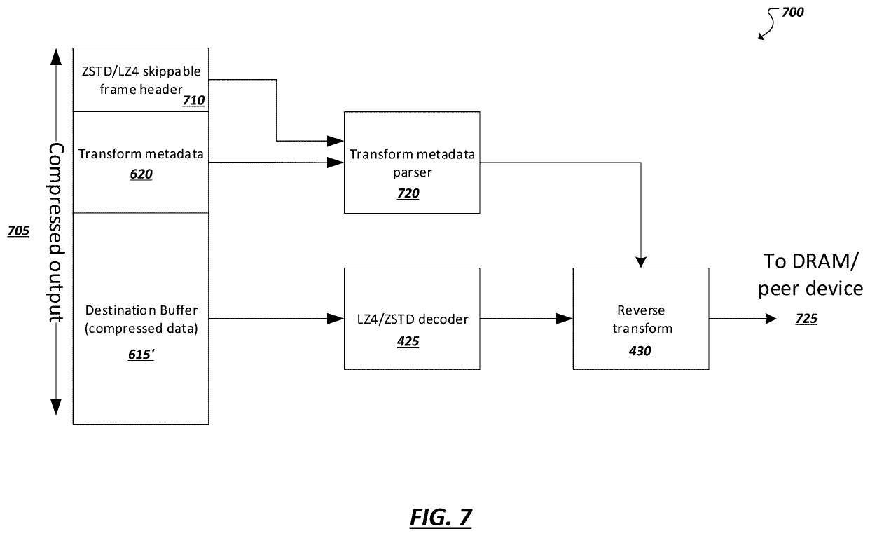

The source data 615 and transform metadata 620 are fed to the data transform and compression circuitry blocks of the hardware accelerator. The hardware accelerator includes logic (e.g., implemented in hardware and/or firmware) to recognize and read the transform metadata (as separate from the data to be compressed) and controls the order in which the source data is processed by respective transform and compression circuitry, as instructed in the transform metadata. Any transforms to the data are performed prior to passing to the compression circuitry to compress the transformed source data. The hardware accelerator, as an output, may write the transformed-compressed source data to a destination buffer with the (e.g., non-transformed, non-compressed) transform metadata. In some implementations, the output may be structured so as to designate (e.g., for the benefit of another system that will later access and decompress the data) the transform metadata as such (e.g., so that it is not erroneously provided for decompression with the compressed source data). In one example implementation, the transform metadata may be provided in the output as a skippable frame (e.g., a LZ4/ZSTF skippable frame). For instance, in the example represented by the simplified block diagram 700 of FIG. 7, the output 705 of a data reduction process performed by the hardware accelerator (e.g., including a series of one or more data transforms followed by a compression of the transformed data) may include a header 710, such as a skippable frame header, in addition to the transform metadata 620 and transformed and compressed data 615′. In some implementations, the header 710 (e.g., according to ZSTD/LZ4) may include a code (e.g., a magic number) that will cause the output 705 to not be rejected by a decompressor 425 (e.g., for failing to include an expected code in the first portion of the data presented to the decompressor, but that will indicate that the a number of bit or bytes of data following the header (corresponding to the transform metadata 620) are to be skipped by the decompressor. In one example, the decompression engine may first parse the skippable frame 710. In the case of LZ4/ZSTD frame formats, skippable frames allow the insertion of user-defined metadata. The skippable frame 710 for the transform metadata 620, in this example, starts with a magic number (e.g., 0x184D2A50) to indicate the presence of the transform metadata. This allows the transform metadata to be handled (and parsed by parser 720) separately from the compressed data 615′, which is provided to the decompressor 425 for decompression (prior to reverse transforms being applied to the data 615′).

While a preprocessing hardware accelerator may be used to transform and compress the data, there may be no guarantee that corresponding hardware (e.g., that can both decompress and perform reverse transforms together and anticipates and understands the transform metadata) will be used or available by the system that later accesses or receives the output 705. In some instances, the system that is to decompress the output may utilize a software- or hardware-based decompressor 425 that is separate from the logic (e.g., 430) used to perform the appropriate reverse transforms on the data 615′. Additionally, the system that processes the output 705 may include a metadata parser 720 (e.g., implemented in hardware, firmware, and/or software) that identifies the transform metadata 620 within the compressed output 705, identifies the series of one or more reversible data transforms applied to the data 615′ and causes the reverse transform logic 430 to perform these reverse transforms (e.g., in reverse order) on the data once it has been decompressed by the decompressor 425. In some implementations, the data processing system accessing the compressed output may be the same system that performed the compression or a different system and may include a hardware accelerator that includes circuitry and/or firmware to implement each of the metadata parser 720, decompressor 425, and reverse transforms 430 using hardware. Indeed, the preprocessing hardware accelerator discussed herein may implement circuitry to perform corresponding data transforms/reverse data transforms and compression/decompression, all within the same hardware accelerator IP block or device, among other example implementations. The resulting output of the reverse transform(s) 430 may restore the data 615′ to its original form for further processing, storage in memory, transmission to another device, etc. (at 725).

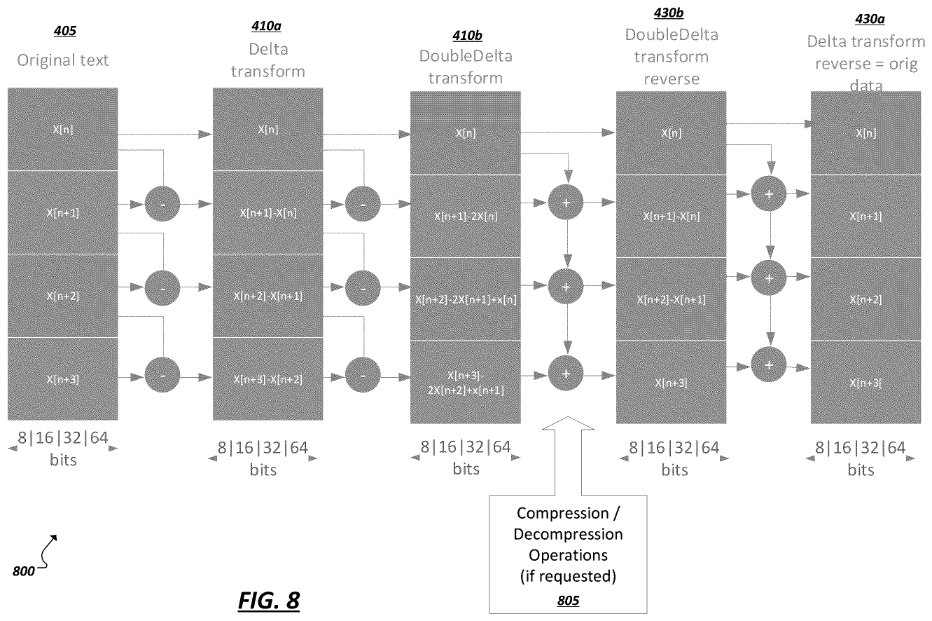

Turning to the block diagram 800 shown in FIG. 8, a series of one or more data transforms may be requested to be applied by a preprocessing hardware accelerator. Reversal of the data transforms is to be applied in the reverse order of the data transforms as applied to the original data (e.g., 405). For instance, in the example of FIG. 8, original source data 405 is provided to a preprocessing hardware accelerator along with a request to apply a particular series of two data transforms: a delta transform 410a followed by a double delta transform 410b. In some implementations, the series of reversible data transforms (e.g., 410a-b) is performed in concert with a compression operation (e.g., 805), all on the preprocessing hardware accelerator in a single, pipelined offload operation. In other cases, the preprocessing hardware accelerator may be called on to perform the data transforms only, without a compression operation (e.g., when a different compressor (e.g., software-based) is to be used instead of the compression circuitry of the preprocessing hardware accelerator. In some implementations, a distinct API call may be provided for “transform-only” operations of the preprocessing hardware accelerator (e.g., with the compression API call used to request transforms included within a compression pipeline). Indeed, compression and decompression 895, if included in the workflow, are to be performed between applying the data transforms (e.g., 410a-b) to the data and applying the corresponding reverse transforms (e.g., 430b-a) to the data. Generally, reverse transforms (e.g., 430b and 430a) are applied in reverse order from the order in which the corresponding transforms (e.g., 410a and 410b respectively) were applied.

In the example of FIG. 8, the first delta transform 410a and the second delta transform 410b (as well as potentially the corresponding reverse transforms 430a, 430b) may represent a selected subset of the reversible data transforms implemented in circuitry of the preprocessing hardware accelerator. An API defined for preprocessing hardware accelerators may be used to select which of the supported data transforms is to be applied to given data and these APIs may be scalable to allow additional, new data transforms to be added to the API for selection by an application (e.g., when the underlying preprocessing hardware accelerator supports the data transform). In this particular example, the delta transform 410a may support a number of data types and granularities (e.g., type UINT with granularities of 8b, 16b, 32b, 64b; for type INT, granularities of 8b, 16b, 32b, 64b; Date, DateTime, DateTime64, among other examples). With the delta transform, the first data value is unmodified, with subsequent data values represented as a difference from a previous one. A size attribute may be defined for the delta transform as well and used to indicate the number of bytes that should be stored after the transform. In the second delta transform 410b various data types and granularities may also be supported (e.g., UINT8, UINT16, UINT32, UINT64, etc.) with the transform 410b applying back-to-back delta transforms will result in a double delta transform. The double data transform may be useful, for instance, in cases of monotonic data such as time series data, dates, integer sequences, etc. that vary gradually (e.g., sensor data), among other examples. Where compression is to be performed following the data transforms, the data 405 is to be transformed at the granularity requested (e.g., in the API call) before it is sent to the compression circuitry (e.g., a HASH unit) for processing. On the decompressor that transform will be reversed after the decompressed data is read out of the history buffer and sent to DRAM.

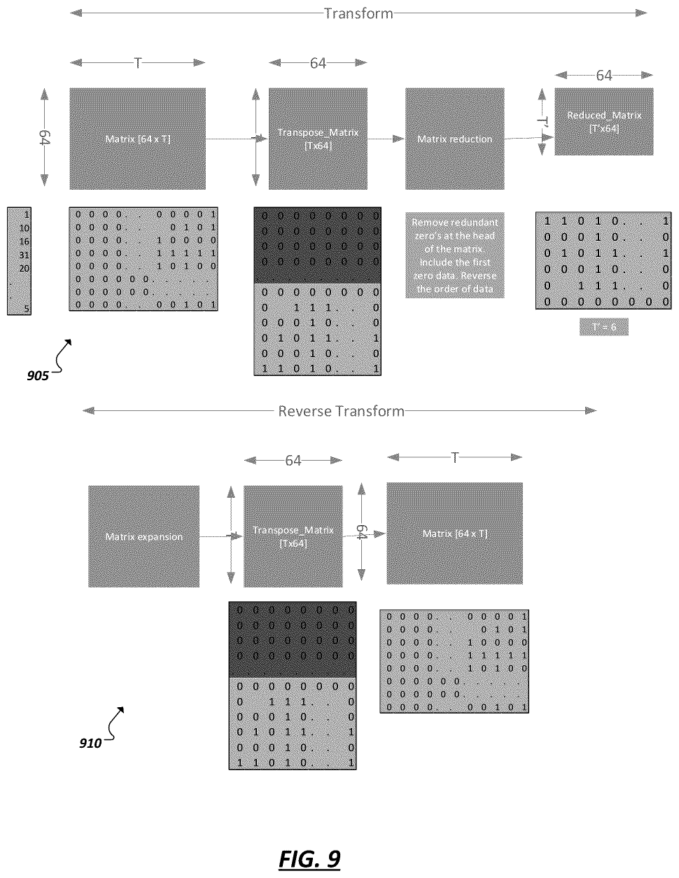

FIG. 9 is a simplified block diagram 900 illustrating the transformation of data (at 905) and corresponding reverse transformation of the data (at 910) using an example T64 data transform, which may also be supported in at least some implementations of an improved preprocessing hardware accelerator. In this example, the T64 may support a variety of data types and granularities (e.g., type UINT with granularities of 8b, 16b, 32b, 64b; for type INT, granularities of 8b, 16b, 32b, 64b; Date, DateTime, DateTime64, among other examples). In a T64 transform, the unused high bits of values in integer data types may be cropped (including Enum, Date and DateTime). At each step of the transform, the hardware accelerator circuitry identifies a block of 64 values, puts them into 64×T bit matrix, and transposes this into a transpose matrix. Circuitry may then perform matrix reduction by scanning the transport matrix from top to bottom and removing redundant zeros at the head to generate a reduced matrix. The reduced matrix may then be output as the result of the transform and sent as an input to another transform in a series or to the compression circuitry (e.g., implementing an LZ77 compressor) of the preprocessing hardware accelerator for compression. For the reverse transform 910, the matrix expansion looks for the first zero, pads the remaining data with zeroes and reverses the order of the data. If there are no zeroes or just one leading zero in a 64B block, no padding is performed. It should be appreciated that the specific data transforms named in this discussion were provided merely as examples of the potentially numerous other (and future) data transforms that may be implemented in hardware of a preprocessing accelerator in concert with compression functionality of the preprocessing accelerator, among other example features and considerations.

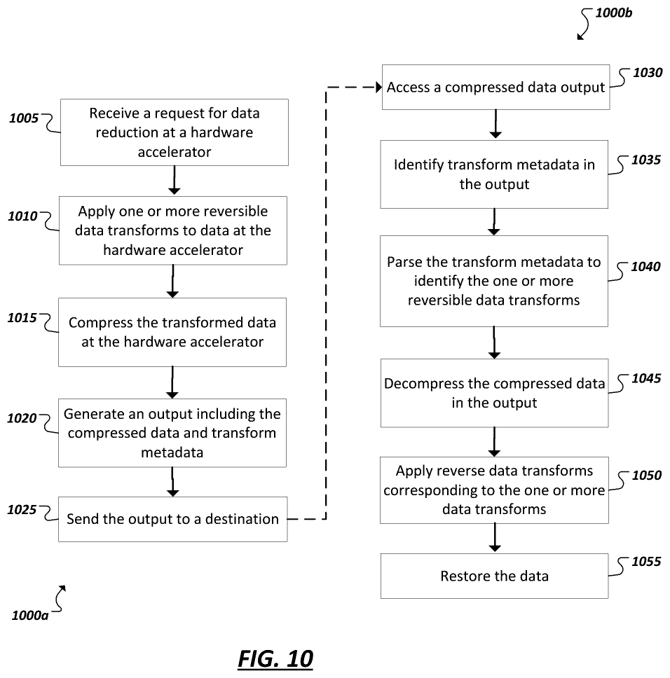

FIG. 10 is a simplified flow diagram 1000a illustrating an example technique for performing a data reduction operation that includes both data transforms and compression in a hardware accelerator as a single offload operation. For instance, a request to perform the data reduction may be received 1005 at the hardware accelerator (e.g., via an API). The request may identify one or more reversible data transforms from a set of data transforms supported by the hardware accelerator to apply to particular data (e.g., in a source buffer). In the case where more than one data transform is to be applied to the data, the request may further specify the order in which the identified data transforms are to be applied, among other example information (e.g., granularity to be applied, the size of the transform output, etc.). The identified data transforms are applied 1010 to the data using hardware circuitry of the hardware accelerator to create a transformed version of the data. The transformed version of the data may then be compressed 1015 using a lossless compression performed by circuitry of the hardware accelerator to generate compressed transformed data based on the request. An output is generated by the hardware accelerator that includes the compressed transformed data together with transform metadata, the transform metadata describing the one or more reversible data transforms applied to the transform metadata. The output may then be sent to a destination (e.g., a destination buffer, system memory, another device over a system bus, another device over a network, etc.).

A decompression technique 1000b is also illustrated, which may follow the example compression technique 1000a. For instance, the compressed data output may be accessed 1030 by another device or the same hardware accelerator, among other examples. The transform metadata present in the output may be identified 1035 (e.g., using a skip header also included in the output) and parsed 1040 to identify the one or more reversible data transforms that were applied to the compressed transformed data present in the output. The compressed transformed data may be selected (to leave off the transform metadata) and decompressed 1045 to generated decompressed transformed data. The information from the transform metadata may then be used to apply 1050 one or more corresponding reverse transforms to the decompressed transformed data (in a sequence reversed from that used to transform the original data) to restore the data 1055 to its original form (e.g., for further processing by the system accessing 1030 the data, among other example features.

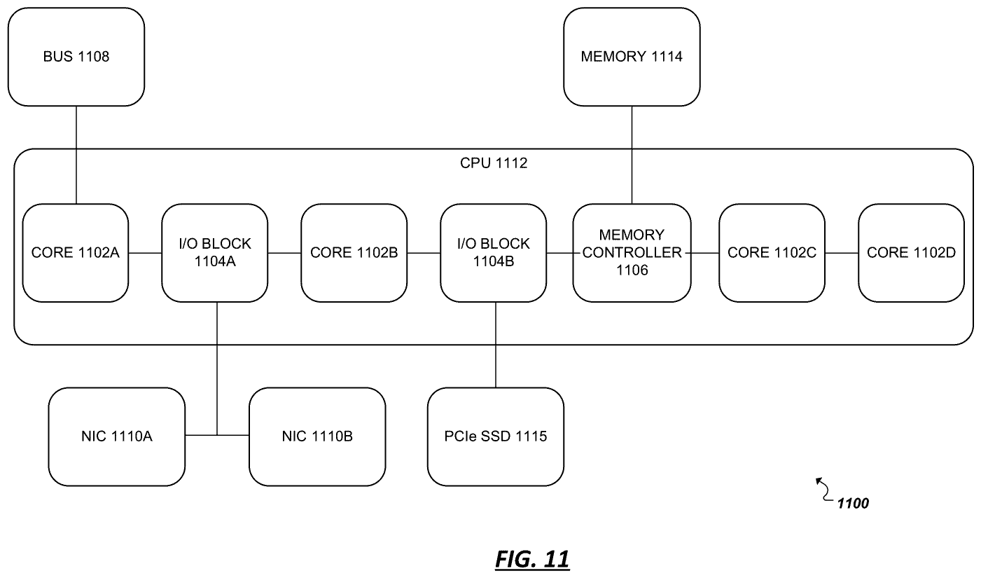

Note that the apparatus', methods', and systems described above may be implemented in any electronic device or system as aforementioned. More particularly, a preprocessing hardware accelerator, such as discussed herein, may be coupled to or integrated in a variety of different electronic devices or system to offload certain preprocessing tasks, including data reduction operations, from other processing hardware (e.g., a CPU) of the system. As a specific illustration, FIG. 11 provides an exemplary implementation of a processing device such as one that may be include or be coupled to and use a preprocessing hardware accelerator (e.g., to offload workloads to). It should be appreciated that other processor architectures may be provided to implement the functionality and processing of requests by an example network processing device, including the implementation of the example network processing device components and functionality discussed above. Further, while the examples discussed above focus on improvements to an Ethernet subsystem and links compliant with an Ethernet-based protocol, it should be appreciated that the principles discussed herein are protocol agnostic and may be applied to interconnects based on a variety of other technologies, such as PCIe, CXL, UCIe, CCIX, Infinity Fabric, among other examples.

Referring to FIG. 11, a block diagram 1100 is shown of an example data processor device (e.g., a central processing unit (CPU)) 1112 coupled to various other components of a platform in accordance with certain embodiments. Although CPU 1112 depicts a particular configuration, the cores and other components of CPU 1112 may be arranged in any suitable manner. CPU 1112 may comprise any processor or processing device, such as a microprocessor, an embedded processor, a digital signal processor (DSP), a network processor, an application processor, a co-processor, a system on a chip (SOC), or other device to execute code. CPU 1112, in the depicted embodiment, includes four processing elements (cores 1102 in the depicted embodiment), which may include asymmetric processing elements or symmetric processing elements. However, CPU 1112 may include any number of processing elements that may be symmetric or asymmetric.

In one embodiment, a processing element refers to hardware or logic to support a software thread. Examples of hardware processing elements include: a thread unit, a thread slot, a thread, a process unit, a context, a context unit, a logical processor, a hardware thread, a core, and/or any other element, which is capable of holding a state for a processor, such as an execution state or architectural state. In other words, a processing element, in one embodiment, refers to any hardware capable of being independently associated with code, such as a software thread, operating system, application, or other code. A physical processor (or processor socket) typically refers to an integrated circuit, which potentially includes any number of other processing elements, such as cores or hardware threads.

A core may refer to logic located on an integrated circuit capable of maintaining an independent architectural state, wherein each independently maintained architectural state is associated with at least some dedicated execution resources. A hardware thread may refer to any logic located on an integrated circuit capable of maintaining an independent architectural state, wherein the independently maintained architectural states share access to execution resources. As can be seen, when certain resources are shared and others are dedicated to an architectural state, the line between the nomenclature of a hardware thread and core overlaps. Yet often, a core and a hardware thread are viewed by an operating system as individual logical processors, where the operating system is able to individually schedule operations on each logical processor.

Physical CPU 1112, as illustrated in FIG. 11, includes four cores—cores 1102A, 1102B, 1102C, and 1102D, though a CPU may include any suitable number of cores. Here, cores 1102 may be considered symmetric cores. In another embodiment, cores may include one or more out-of-order processor cores or one or more in-order processor cores. However, cores 1102 may be individually selected from any type of core, such as a native core, a software managed core, a core adapted to execute a native Instruction Set Architecture (ISA), a core adapted to execute a translated ISA, a co-designed core, or other known core. In a heterogeneous core environment (e.g., asymmetric cores), some form of translation, such as binary translation, may be utilized to schedule or execute code on one or both cores.

A core 1102 may include a decode module coupled to a fetch unit to decode fetched elements. Fetch logic, in one embodiment, includes individual sequencers associated with thread slots of cores 1102. Usually a core 1102 is associated with a first ISA, which defines/specifies instructions executable on core 1102. Often machine code instructions that are part of the first ISA include a portion of the instruction (referred to as an opcode), which references/specifies an instruction or operation to be performed. The decode logic may include circuitry that recognizes these instructions from their opcodes and passes the decoded instructions on in the pipeline for processing as defined by the first ISA. For example, as decoders may, in one embodiment, include logic designed or adapted to recognize specific instructions, such as transactional instructions. As a result of the recognition by the decoders, the architecture of core 1102 takes specific, predefined actions to perform tasks associated with the appropriate instruction. It is important to note that any of the tasks, blocks, operations, and methods described herein may be performed in response to a single or multiple instructions; some of which may be new or old instructions. Decoders of cores 1102, in one embodiment, recognize the same ISA (or a subset thereof). Alternatively, in a heterogeneous core environment, a decoder of one or more cores (e.g., core 1102B) may recognize a second ISA (either a subset of the first ISA or a distinct ISA).

In various embodiments, cores 1102 may also include one or more arithmetic logic units (ALUs), floating point units (FPUs), caches, instruction pipelines, interrupt handling hardware, registers, or other suitable hardware to facilitate the operations of the cores 1102.

Bus 1108 may represent any suitable interconnect coupled to CPU 1112. In one example, bus 1108 may couple CPU 1112 to another CPU of platform logic (e.g., via UPI). I/O blocks 1104 represents interfacing logic to couple I/O devices 1110 and 1115 to cores of CPU 1112. In various embodiments, an I/O block 1104 may include an I/O controller that is integrated onto the same package as cores 1102 or may simply include interfacing logic to couple to an I/O controller that is located off-chip. As one example, I/O blocks 1104 may include PCIe interfacing logic. Similarly, memory controller 1106 represents interfacing logic to couple memory 1114 to cores of CPU 1112. In various embodiments, memory controller 1106 is integrated onto the same package as cores 1102. In alternative embodiments, a memory controller could be located off chip.

As various examples, in the embodiment depicted, core 1102A may have a relatively high bandwidth and lower latency to devices coupled to bus 1108 (e.g., other CPUs 1112) and to NICs 1110, but a relatively low bandwidth and higher latency to memory 1114 or core 1102D. Core 1102B may have relatively high bandwidths and low latency to both NICs 1110 and PCIe solid state drive (SSD) 1115 and moderate bandwidths and latencies to devices coupled to bus 1108 and core 1102D. Core 1102C would have relatively high bandwidths and low latencies to memory 1114 and core 1102D. Finally, core 1102D would have a relatively high bandwidth and low latency to core 1102C, but relatively low bandwidths and high latencies to NICs 1110, core 1102A, and devices coupled to bus 1108.

“Logic” (e.g., as found in I/O controllers, power managers, latency managers, etc. and other references to logic in this application) may refer to hardware, firmware, software and/or combinations of each to perform one or more functions. In various embodiments, logic may include a microprocessor or other processing element operable to execute software instructions, discrete logic such as an application specific integrated circuit (ASIC), a programmed logic device such as a field programmable gate array (FPGA), a memory device containing instructions, combinations of logic devices (e.g., as would be found on a printed circuit board), or other suitable hardware and/or software. Logic may include one or more gates or other circuit components. In some embodiments, logic may also be fully embodied as software.

A design may go through various stages, from creation to simulation to fabrication. Data representing a design may represent the design in a number of manners. First, as is useful in simulations, the hardware may be represented using a hardware description language (HDL) or another functional description language. Additionally, a circuit level model with logic and/or transistor gates may be produced at some stages of the design process. Furthermore, most designs, at some stage, reach a level of data representing the physical placement of various devices in the hardware model. In the case where conventional semiconductor fabrication techniques are used, the data representing the hardware model may be the data specifying the presence or absence of various features on different mask layers for masks used to produce the integrated circuit. In some implementations, such data may be stored in a database file format such as Graphic Data System II (GDS II), Open Artwork System Interchange Standard (OASIS), or similar format.

In some implementations, software-based hardware models, and HDL and other functional description language objects can include register transfer language (RTL) files, among other examples. Such objects can be machine-parsable such that a design tool can accept the HDL object (or model), parse the HDL object for attributes of the described hardware, and determine a physical circuit and/or on-chip layout from the object. The output of the design tool can be used to manufacture the physical device. For instance, a design tool can determine configurations of various hardware and/or firmware elements from the HDL object, such as bus widths, registers (including sizes and types), memory blocks, physical link paths, fabric topologies, among other attributes that would be implemented in order to realize the system modeled in the HDL object. Design tools can include tools for determining the topology and fabric configurations of system on chip (SoC) and other hardware device. In some instances, the HDL object can be used as the basis for developing models and design files that can be used by manufacturing equipment to manufacture the described hardware. Indeed, an HDL object itself can be provided as an input to manufacturing system software to cause the described hardware.

In any representation of the design, the data may be stored in any form of a machine readable medium. A memory or a magnetic or optical storage such as a disc may be the machine-readable medium to store information transmitted via optical or electrical wave modulated or otherwise generated to transmit such information. When an electrical carrier wave indicating or carrying the code or design is transmitted, to the extent that copying, buffering, or re-transmission of the electrical signal is performed, a new copy is made. Thus, a communication provider or a network provider may store on a tangible, machine-readable medium, at least temporarily, an article, such as information encoded into a carrier wave, embodying techniques of embodiments of the present disclosure.

A module as used herein refers to any combination of hardware, software, and/or firmware. As an example, a module includes hardware, such as a micro-controller, associated with a non-transitory medium to store code adapted to be executed by the microcontroller. Therefore, reference to a module, in one embodiment, refers to the hardware, which is specifically configured to recognize and/or execute the code to be held on a non-transitory medium. Furthermore, in another embodiment, use of a module refers to the non-transitory medium including the code, which is specifically adapted to be executed by the microcontroller to perform predetermined operations. And as can be inferred, in yet another embodiment, the term module (in this example) may refer to the combination of the microcontroller and the non-transitory medium. Often module boundaries that are illustrated as separate commonly vary and potentially overlap. For example, a first and a second module may share hardware, software, firmware, or a combination thereof, while potentially retaining some independent hardware, software, or firmware. In one embodiment, use of the term logic includes hardware, such as transistors, registers, or other hardware, such as programmable logic devices.

Use of the phrase ‘to’ or ‘configured to,’ in one embodiment, refers to arranging, putting together, manufacturing, offering to sell, importing and/or designing an apparatus, hardware, logic, or element to perform a designated or determined task. In this example, an apparatus or element thereof that is not operating is still ‘configured to’ perform a designated task if it is designed, coupled, and/or interconnected to perform said designated task. As a purely illustrative example, a logic gate may provide a 0 or a 1 during operation. But a logic gate ‘configured to’ provide an enable signal to a clock does not include every potential logic gate that may provide a 1 or 0. Instead, the logic gate is one coupled in some manner that during operation the 1 or 0 output is to enable the clock. Note once again that use of the term ‘configured to’ does not require operation, but instead focus on the latent state of an apparatus, hardware, and/or element, where in the latent state the apparatus, hardware, and/or element is designed to perform a particular task when the apparatus, hardware, and/or element is operating.

Furthermore, use of the phrases ‘capable of/to,’ and or ‘operable to,’ in one embodiment, refers to some apparatus, logic, hardware, and/or element designed in such a way to enable use of the apparatus, logic, hardware, and/or element in a specified manner Note as above that use of to, capable to, or operable to, in one embodiment, refers to the latent state of an apparatus, logic, hardware, and/or element, where the apparatus, logic, hardware, and/or element is not operating but is designed in such a manner to enable use of an apparatus in a specified manner.

A value, as used herein, includes any known representation of a number, a state, a logical state, or a binary logical state. Often, the use of logic levels, logic values, or logical values is also referred to as 1's and 0's, which simply represents binary logic states. For example, a 1 refers to a high logic level and 0 refers to a low logic level. In one embodiment, a storage cell, such as a transistor or flash cell, may be capable of holding a single logical value or multiple logical values. However, other representations of values in computer systems have been used. For example, the decimal number ten may also be represented as a binary value of 418A0 and a hexadecimal letter A. Therefore, a value includes any representation of information capable of being held in a computer system.

Moreover, states may be represented by values or portions of values. As an example, a first value, such as a logical one, may represent a default or initial state, while a second value, such as a logical zero, may represent a non-default state. In addition, the terms reset and set, in one embodiment, refer to a default and an updated value or state, respectively. For example, a default value potentially includes a high logical value, or reset, while an updated value potentially includes a low logical value, or set. Note that any combination of values may be utilized to represent any number of states.

The embodiments of methods, hardware, software, firmware, or code set forth above may be implemented via instructions or code stored on a machine-accessible, machine readable, computer accessible, or computer readable medium which are executable by a processing element. A non-transitory machine-accessible/readable medium includes any mechanism that provides (i.e., stores and/or transmits) information in a form readable by a machine, such as a computer or electronic system. For example, a non-transitory machine-accessible medium includes random-access memory (RAM), such as static RAM (SRAM) or dynamic RAM (DRAM); ROM; magnetic or optical storage medium; flash memory devices; electrical storage devices; optical storage devices; acoustical storage devices; other form of storage devices for holding information received from transitory (propagated) signals (e.g., carrier waves, infrared signals, digital signals); etc., which are to be distinguished from the non-transitory mediums that may receive information there from.

Instructions used to program logic to perform embodiments of the disclosure may be stored within a memory in the system, such as DRAM, cache, flash memory, or other storage. Furthermore, the instructions can be distributed via a network or by way of other computer readable media. Thus a machine-readable medium may include any mechanism for storing or transmitting information in a form readable by a machine (e.g., a computer), but is not limited to, floppy diskettes, optical disks, Compact Disc, Read-Only Memory (CD-ROMs), and magneto-optical disks, Read-Only Memory (ROMs), Random Access Memory (RAM), Erasable Programmable Read-Only Memory (EPROM), Electrically Erasable Programmable Read-Only Memory (EEPROM), magnetic or optical cards, flash memory, or a tangible, machine-readable storage used in the transmission of information over the Internet via electrical, optical, acoustical or other forms of propagated signals (e.g., carrier waves, infrared signals, digital signals, etc.). Accordingly, the computer-readable medium includes any type of tangible machine-readable medium suitable for storing or transmitting electronic instructions or information in a form readable by a machine (e.g., a computer).

The following examples pertain to embodiments in accordance with this Specification. Example 1 is an apparatus including: a hardware accelerator device including: one or more interfaces to receive a request to perform one or more data reduction operations on a data; transform circuitry to apply a set of reversible data transforms on the data based on the request to generate transformed data; and compression circuitry to compress the transformed data to generate compressed transformed data; and output circuitry to generate an output of the one or more data reduction operations, the output includes the compressed transformed data and transform metadata, and the transform metadata indicates the set of reversible data transforms applied to the compressed transformed data.

Example 2 includes the subject matter of example 1, where the data is read from system memory and the output is written to system memory to correspond to the request in a single offload operation.

Example 3 includes the subject matter of any one of examples 1-2, where the request is received from an application through an application programming interface (API) defined for the hardware accelerator device.

Example 4 includes the subject matter of any one of examples 1-3, where the set of reversible data transforms includes a plurality of reversible data transforms to be applied in a particular sequence based on the request to generate the transformed data.

Example 5 includes the subject matter of example 4, where the transform metadata identifies the particular sequence.

Example 6 includes the subject matter of any one of examples 1-5, where the output further includes header data to indicate the presence of the transform metadata and prevent the transform metadata from being decompressed by a decompressor in a subsequent operation.

Example 7 includes the subject matter of example 6, where the header data includes a code to indicate that the output includes the transform metadata to be skipped by the decompressor during decompression.

Example 8 includes the subject matter of any one of examples 1-7, where the output is to be sent over an interconnect to another device.

Example 9 includes the subject matter of any one of examples 1-8, where the data is compressed according to a lossless compression algorithm.

Example 10 includes the subject matter of any one of examples 1-9, where the request includes a listing of the set of reversible data transforms to be applied to the data.

Example 11 includes the subject matter of example 10, where the listing identifies a corresponding granularity for each of the set of reversible data transforms.

Example 12 includes the subject matter of any one of examples 1-11, further including: parsing logic to: identify transform metadata of other compressed data; and determine a sequence of transforms applied to the other compressed data based on the transform metadata for the other compressed data; decompression circuitry to decompress the other compressed data to generated decompressed transformed data; and reverse transformation circuitry to apply the transforms in the sequence of transforms to the decompressed transformed data in a reverse order from the sequence of transforms identified in the transform metadata of the other compressed data.

Example 13 includes the subject matter of any one of examples 1-12, where the set of reversible data transforms includes at least one of a delta transform, a double delta transform, a T64 transform, a Burrows-Wheeler transform, or a XOR transform.

Example 14 includes the subject matter of any one of examples 1-13, where the preprocessing accelerator device further includes cryptographic circuitry to perform one of encryption or decryption of data.

Example 15 is a method including: receiving, at a hardware accelerator in a system, a request to perform one or more data reduction operations on data; applying one or more reversible data transforms on the data, using hardware circuitry of the hardware accelerator, based on the request to generate transformed data; compress the transformed data, using hardware circuitry of the hardware accelerator, to generate compressed transformed data; and generating an output of the one or more data reduction operations, where the output includes the compressed transformed data and transform metadata, and the transform metadata indicates the one or more reversible data transforms applied to the compressed transformed data.

Example 16 includes the subject matter of example 15, further including: accessing the output; parsing the transform metadata to identify the one or more reversible data transforms; decompressing the compressed transformed data to generate decompressed transformed data; and applying reverse transforms corresponding to the set of reversible data transforms to the decompressed transformed data to restore the data.

Example 17 includes the subject matter of any one of examples 15-16, where the request includes a request to offload transformation and compression of the data from a central processing unit (CPU) to the hardware accelerator in a single offload operation.

Example 18 includes the subject matter of any one of examples 15-17, where the request is received from an application through an application programming interface (API) defined for the hardware accelerator device.

Example 19 includes the subject matter of any one of examples 15-18, where the set of reversible data transforms includes a plurality of reversible data transforms to be applied in a particular sequence based on the request to generate the transformed data.

Example 20 includes the subject matter of example 19, where the transform metadata identifies the particular sequence.

Example 21 includes the subject matter of any one of examples 15-20, where the output further includes header data to indicate the presence of the transform metadata and prevent the transform metadata from being decompressed by a decompressor in a subsequent operation.

Example 22 includes the subject matter of example 21, where the header data includes a code to indicate that the output includes the transform metadata to be skipped by the decompressor during decompression.

Example 23 includes the subject matter of any one of examples 15-22, further including sending the output over an interconnect to another device.

Example 24 includes the subject matter of any one of examples 15-23, where the data is compressed according to a lossless compression algorithm.

Example 25 includes the subject matter of any one of examples 15-24, where the request includes a listing of the set of reversible data transforms to be applied to the data.

Example 26 includes the subject matter of example 25, where the listing identifies a corresponding granularity for each of the set of reversible data transforms.

Example 27 includes the subject matter of any one of examples 15-26, where the set of reversible data transforms includes at least one of a delta transform, a double delta transform, a T64 transform, a Burrows-Wheeler transform, or a XOR transform.

Example 28 includes the subject matter of any one of examples 15-27, further including, using hardware circuitry of the hardware accelerator, encrypting the data.

Example 29 is a system including means to perform the method of any one of examples 15-28.

Example 30 includes the subject matter of example 29, where the means include a non-transitory machine-readable storage medium with instructions stored thereon, the instructions executable to cause a machine to perform at least a portion of the method of any one of examples 15-28.

Example 31 is a system including: a processor device; a memory; a hardware accelerator coupled to the processor device and the memory, where the hardware accelerator includes circuitry to: receive a request to perform data reduction on particular data in the memory, where the request identifies as set of reversible data transforms to be applied to the particular data prior to compression of the particular data; apply the set of reversible data transforms to the data to generate transformed data; compress the transformed data to generate compressed transformed data; and generate an output to include the compressed transformed data and transform metadata, where the transform metadata indicates the set of reversible data transforms applied to the compressed transformed data.

Example 32 includes the subject matter of example 31, further including a device to: access the output; parse the transform metadata to identify the set of reversible data transforms applied to the compressed transformed data; decompress the compressed transformed data to generate decompressed transformed data; and apply a set of reverse transforms to the decompressed transformed data to restore the particular data.

Example 33 includes the subject matter of any one of examples 31-32, where the particular data includes one of a plurality of segments of a dataset and the hardware accelerator is to apply the set of reversible data transforms and compress each of the plurality of segments of the dataset for an application executed by the processor device.

Example 34 includes the subject matter of any one of examples 31-33, where the request is received from an application through an application programming interface (API) defined for the hardware accelerator device.

Example 35 includes the subject matter of any one of examples 31-34, where the set of reversible data transforms includes a plurality of reversible data transforms to be applied in a particular sequence based on the request to generate the transformed data.

Example 36 includes the subject matter of example 35, where the transform metadata identifies the particular sequence.

Example 37 includes the subject matter of any one of examples 31-36, where the output further includes header data to indicate the presence of the transform metadata and prevent the transform metadata from being decompressed by a decompressor in a subsequent operation.

Example 38 includes the subject matter of example 37, where the header data includes a code to indicate that the output includes the transform metadata to be skipped by the decompressor during decompression.

Example 39 includes the subject matter of any one of examples 31-38, where the output is to be sent over an interconnect to another device.

Example 40 includes the subject matter of any one of examples 31-39, where the data is compressed according to a lossless compression algorithm.

Example 41 includes the subject matter of any one of examples 31-40, where the request includes a listing of the set of reversible data transforms to be applied to the data.

Example 42 includes the subject matter of example 41, where the listing identifies a corresponding granularity for each of the set of reversible data transforms.

Example 43 includes the subject matter of any one of examples 31-42, where the set of reversible data transforms includes at least one of a delta transform, a double delta transform, a T64 transform, a Burrows-Wheeler transform, or a XOR transform.

Example 44 includes the subject matter of any one of examples 31-43, further including, using hardware circuitry of the hardware accelerator, encrypting the data.

Example 45 includes the subject matter of any one of examples 31-44, where the request includes a request to offload transformation and compression of the data from processor device to the hardware accelerator in a single offload operation.

Example 46 includes the subject matter of any one of examples 31-45, where the system includes a personal computer.

Example 47 includes the subject matter of any one of examples 31-45, where the system includes a server platform.

Example 48 includes the subject matter of any one of examples 31-45, where the system includes a smart phone.

Reference throughout this specification to “one embodiment” or “an embodiment” means that a particular feature, structure, or characteristic described in connection with the embodiment is included in at least one embodiment of the present disclosure. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

In the foregoing specification, a detailed description has been given with reference to specific exemplary embodiments. It will, however, be evident that various modifications and changes may be made thereto without departing from the broader spirit and scope of the disclosure as set forth in the appended claims. The specification and drawings are, accordingly, to be regarded in an illustrative sense rather than a restrictive sense. Furthermore, the foregoing use of embodiment and other exemplarily language does not necessarily refer to the same embodiment or the same example, but may refer to different and distinct embodiments, as well as potentially the same embodiment.

What is claimed is:

1. An apparatus comprising:
a hardware accelerator device comprising:
one or more interfaces to receive a request to perform one or more data reduction operations on a data;
transform circuitry to apply a set of reversible data transforms on the data based on the request to generate transformed data; and
compression circuitry to compress the transformed data to generate compressed transformed data; and
output circuitry to generate an output of the one or more data reduction operations, the output comprises the compressed transformed data and transform metadata, and the transform metadata indicates the set of reversible data transforms applied to the compressed transformed data.

2. The apparatus of claim 1, wherein the data is read from system memory and the output is written to system memory to correspond to the request in a single offload operation.

3. The apparatus of claim 1, wherein the request is received from an application through an application programming interface (API) defined for the hardware accelerator device.

4. The apparatus of claim 1, wherein the set of reversible data transforms comprises a plurality of reversible data transforms to be applied in a particular sequence based on the request to generate the transformed data.

5. The apparatus of claim 4, wherein the transform metadata identifies the particular sequence.

6. The apparatus of claim 1, wherein the output further comprises header data to indicate the presence of the transform metadata and prevent the transform metadata from being decompressed by a decompressor in a subsequent operation.

7. The apparatus of claim 6, wherein the header data comprises a code to indicate that the output comprises the transform metadata to be skipped by the decompressor during decompression.

8. The apparatus of claim 1, wherein the output is to be sent over an interconnect to another device.

9. The apparatus of claim 1, wherein the data is compressed according to a lossless compression algorithm.

10. The apparatus of claim 1, wherein the request comprises a listing of the set of reversible data transforms to be applied to the data.

11. The apparatus of claim 10, wherein the listing identifies a corresponding granularity for each of the set of reversible data transforms.

12. The apparatus of claim 1, further comprising:
parsing logic to:
identify transform metadata of other compressed data; and
determine a sequence of transforms applied to the other compressed data based on the transform metadata for the other compressed data;
decompression circuitry to decompress the other compressed data to generated decompressed transformed data; and
reverse transformation circuitry to apply the transforms in the sequence of transforms to the decompressed transformed data in a reverse order from the sequence of transforms identified in the transform metadata of the other compressed data.

13. The apparatus of claim 1, wherein the set of reversible data transforms comprises at least one of a delta transform, a double delta transform, a T64 transform, a Burrows-Wheeler transform, or a XOR transform.

14. The apparatus of claim 1, wherein the preprocessing accelerator device further comprises cryptographic circuitry to perform one of encryption or decryption of data.

15. A method comprising:
receiving, at a hardware accelerator in a system, a request to perform one or more data reduction operations on data;
applying one or more reversible data transforms on the data, using hardware circuitry of the hardware accelerator, based on the request to generate transformed data;
compress the transformed data, using hardware circuitry of the hardware accelerator, to generate compressed transformed data; and
generating an output of the one or more data reduction operations, wherein the output comprises the compressed transformed data and transform metadata, and the transform metadata indicates the one or more reversible data transforms applied to the compressed transformed data.

16. The method of claim 15, further comprising:
accessing the output;
parsing the transform metadata to identify the one or more reversible data transforms;
decompressing the compressed transformed data to generate decompressed transformed data; and
applying reverse transforms corresponding to the set of reversible data transforms to the decompressed transformed data to restore the data.

17. The method of claim 15, wherein the request comprises a request to offload transformation and compression of the data from a central processing unit (CPU) to the hardware accelerator in a single offload operation.

18. A system comprising:
a processor device;
a memory;
a hardware accelerator coupled to the processor device and the memory, wherein the hardware accelerator comprises circuitry to:
receive a request to perform data reduction on particular data in the memory, wherein the request identifies as set of reversible data transforms to be applied to the particular data prior to compression of the particular data;
apply the set of reversible data transforms to the data to generate transformed data;
compress the transformed data to generate compressed transformed data; and
generate an output to comprise the compressed transformed data and transform metadata, wherein the transform metadata indicates the set of reversible data transforms applied to the compressed transformed data.

19. The system of claim 18, further comprising a device to:
access the output;
parse the transform metadata to identify the set of reversible data transforms applied to the compressed transformed data;
decompress the compressed transformed data to generate decompressed transformed data; and
apply a set of reverse transforms to the decompressed transformed data to restore the particular data.

20. The system of claim 18, wherein the particular data comprises one of a plurality of segments of a dataset and the hardware accelerator is to apply the set of reversible data transforms and compress each of the plurality of segments of the dataset for an application executed by the processor device.
